(19) United States
(12) Patent Application Publication
(10) Pub. No.: US 2026/0112399 A1
(43) Pub. Date: Apr. 23, 2026

(54) RESISTIVE-TYPE MEMORY DEVICE WITH REFERENCE CIRCUIT FOR WIDE MARGIN CURRENT SENSE AMPLIFIER AND METHOD OF OPERATION

(71) Applicant: IM2 Solutions, Inc., Pleasanton, CA (US)

(72) Inventor: Tim LAO, Sacramento, CA (US)

(21) Appl. No.: 19/363,553

(22) Filed: Oct. 20, 2025

Related U.S. Application Data
(60) Provisional application No. 63/709,514, filed on Oct. 20, 2024.

(51) Int. Cl. G11C 11/16

(52) U.S. Cl. CPC G11C 11/1673; G11C 11/1675; G11C 11/1697; G11C 11/1655; G11C 11/1657

(57) ABSTRACT

A resistive-type memory device comprises at least one memory array. Each memory array includes reference cells and a reference generator that generates a reference voltage that is midway between a first voltage and a second voltage, the first voltage being a function of a first current through a first reference cell, the second voltage being a function of a second current through a second reference cell, the first reference cell and the second reference cell being a pair of reference cells storing complementary values in a row of the memory array. The reference voltage is thus automatically centered and tracks the variation in a read current for all PVT corners without the need of tuning and adjustment of the reference voltage. This reference generator works with a current sense amplifier in certain implementation examples to reliably output the correct read data for all PVT corners.

### CROSS REFERENCE TO RELATED APPLICATION

The present application claims the benefit of priority to U.S. Provisional Patent Application No. 63/709,514, filed Oct. 20, 2024, entitled “Reference Circuit for Wide Margin Resistive Type Memory Current Sense Amplifier and Method of operation,” which is incorporated herein by reference in its entirety.

### FIELD

The present application is related to resistive-type memory devices, and more particularly to a resistive-type device with reference circuit for wide margin resistive type memory current sense amplifier and method of operation.

### BACKGROUND

The resistance of a magnetic tunnel junction structure (MTJ) is known to have significant variation with respect to process and temperature. The transistors (access transistors, read pass gates, resistive and capacitive loads, etc.) that are built around the MTJ and along the read path are also well known to have significant variation with respect to process, voltage, and temperature (PVT). Since the read current is a function of these resistance components, the variation also manifests itself in the read current.

One of the challenges in the design of magneto-resistive random-access memory (MRAM, such as one-transistor one-MTJ MRAM or 1T1M MRAM) is designing a reference (reference voltage or reference current) for a sense amplifier that, along with the read current, allow successfully determination of the correct output data in most cases despite all these variations.

Some of the conventional methods of generating the reference include generating a reference current from reading a ‘0’ (Rp) and another reference current from reading a ‘1’ (Rap), and then use some circuit technique to generate the average of these 2 currents as the reference. Some method also uses tuning and adjustment by means of state machine or some other logic design to tune and center this reference level in case of variation in the read current.

### SUMMARY

The present disclosure provides examples of a reference generator that generates a reference voltage level that is automatically centered and tracks the variation in the read current for all PVT corners without the need of tuning and adjustment of the reference voltage. This reference generator works with a current sense amplifier in some implementation examples to reliably output the correct data for all PVT corners.

In some implementation examples, a resistive type memory device, e.g., a magneto-resistive random-access memory (MRAM) device, comprises at least one memory array, the at least one memory array including a first memory array, e.g., an MRAM array. The first memory array including a plurality of rows and a plurality of columns, the plurality of columns including at least one column group, the at least one column group including a first column group, the first column group including a number of columns of bit cells and a pair of columns of reference cells, the pair of columns of reference cells including a pair of reference cells configured to store complementary data values in each row of the plurality of rows.

The first memory array further comprises at least one reference generator and sense amplifier block corresponding, respectively, to the at least one column group, the at least one reference generator and sense amplifier block including a first reference generator and sense amplifier block corresponding to the first column group, the first reference generator and sense amplifier block including a reference generator corresponding to the pair of columns of reference cells and a number of sense amplifiers, the number of sense amplifiers including a respective sense amplifier corresponding, to each column of the number of columns of bit cells.

In some implementation examples, the reference generator is configured to output a reference voltage to each of the number of sense amplifiers during a read operation to read from one or more bit cells in a row of the memory array, the reference voltage being midway between a first voltage and a second voltage, the first voltage being a function of a first current through a first reference cell, the second voltage being a function of a second current through a second reference cell, the first reference cell and the second reference cell being a pair of reference cells in the row and in the pair of columns of reference cells.

In some implementation examples, the reference generator includes first and second amplifier stages, the first amplifier stage is configured to generate a third voltage and a fourth voltage in response to the first current and the second current during the read operation, the second amplifier stage is configured to generate the reference voltage in response to the first voltage and the second voltage.

In some implementation examples, the second amplifier stage includes first and second differential amplifiers. The first differential amplifier has a pair of inputs configured to receive the third voltage and the fourth voltage, respectively, and a first internal reference node configured to reach the first voltage in response to the third voltage and the fourth voltage. The second differential amplifier has a pair of inputs configured to receive the fourth voltage and the third voltage, respectively, and a second internal reference node configured to reach the second voltage in response to the fourth voltage and the third voltage. The first differential amplifier and the second differential amplifier each has an output coupled to the output of the reference generator.

In some implementation examples, the reference generator further includes a first input configured to conduct the first current, and a second input configured to conduct the second current. The first amplifier stage includes a first transistor having a current-carrying terminal coupled to the first input, and a second transistor having a current-carrying terminal coupled to the second input. The reference generator further includes a clamping circuit configured to generate a clamp voltage during the read operation, the clamp voltage being applied to a gate terminal of the first transistor and a gate terminal of the second transistor thereby preventing the first current and the second current from being above a predetermined threshold current.

In some implementation examples, a respective sense amplifier of the number of sense amplifiers includes a current sense amplifier configured to receive the reference voltage from the reference generator and a read current from a respective bit cell in the row of memory array during the read operation, and to output a differential voltage indicating a level of the read current.

In some implementation examples, the current sense amplifier includes third and fourth differential amplifiers configured to output the differential voltage in response to the read current and the reference voltage.

In some implementation examples, the resistive-type memory device further comprises a plurality of local drive units, each respective local drive unit being coupled to a respective column of the plurality of columns via a respective source line (SL) and a respective bit line (BL), the plurality of local drive units including first and second local drive units corresponding to the pair of columns of reference cells, respectively.

In some implementation examples, the resistive-type memory device further comprises a plurality of global driver circuits including a number of global driver circuits corresponding, respectively, to the number of sense amplifiers, and first and second global driver circuits corresponding to first and second inputs of the reference generator, respectively.

In some implementation examples, during the read operation, the first global driver circuit is configured to drive the first current between the first input of the reference generator and the first local drive unit, and the first local drive unit is configured to drive the first current between the first global driver circuit and the first reference cell. In some implementation examples, during the read operation, the second global driver circuit is configured to drive the second current between the second input of the reference generator and the second local drive unit, and the second local drive unit is configured to drive the second current between the second global drive circuit and the second reference cell.

In some implementation examples, during the read operation, a respective global driver circuit of the number of global driver circuits is configured to drive a read current between a respective sense amplifier of the number of sense amplifiers and a respective local drive unit, and the respective local drive unit is configured to drive the read current between the respective global driver circuit and a respective bit cell in the row of the memory array.

In some implementation examples, a method of operating the resistive-type memory device comprises writing reference cell data into a pair of columns of reference cells associated with the first column group, whereby a pair of reference cells in each row of the pair of columns of reference cells store complementary data values; and performing a read operation to read one or more bit cells in a selected row of the memory array, including:
driving a first current through a first reference cell and a second current through a second reference cell, the first reference cell and the second reference cell being a pair of reference cells in the selected row and in the pair of columns of reference cells;
outputting a reference voltage, the reference voltage being midway between a first voltage and a second voltage, the first voltage being a function of the first current, the second voltage being a function of the second current; and
applying the reference voltage to one or more current sense amplifiers configured to sense one or more read currents from the one or more bit cells, respectively.

In some implementation examples, driving a first current from a reference generator through a first reference cell and a second current from the reference generator through a second reference cell includes driving the first current using a first local drive unit and driving the second current using a second local drive unit, the first and second local drive units corresponding to the pair of columns of reference cells, respectively.

In some implementation examples, driving a first current from a reference generator through a first reference cell and a second current from the reference generator through a second reference cell further includes driving the first current using a first global driver circuit and driving the second current using a second global driver circuit, the first and second global driver circuits corresponding to first and second inputs, respectively, of a reference generator that outputs the reference voltage.

In some implementation examples, the method of operating the resistive-type memory device further comprises, during the read operation, driving each of one or more read currents between a respective sense amplifier of the one or more sense amplifiers and a respective bit cell of the one or more bit cells.

### BRIEF DESCRIPTION OF THE DRAWINGS

The present implementation examples are illustrated by way of example and not intended to be limitation in the figures of the accompanying drawings. In general, the implementation examples may be better understood by referring to the following figures. The components in the figures are not necessarily to scale, emphasis instead being placed upon illustrating the principles of the invention. In the figures, like reference numerals may designate corresponding parts throughout the different views.

FIG. 1A is a block diagram illustrating an MRAM device including an array of MRAM array tiles (MATs), local drive circuits associated with respective MATs, a row decoder circuit associated with each row of MATs, and a column decoder circuit and read/write drive circuit associated with each column of MATs, in accordance with the present disclosure.

FIG. 1B is a block diagram illustrating part of the MRAM device showing an MAT including an N by M (N×M) MRAM memory array (N=n+1, M=m+1), a reference bit cells block, global read/write (R/W) circuitry, local drive units, and row and column decode and control circuits, in accordance with the present disclosure.

FIG. 1C is a block diagram showing each local drive unit as including a array column select (CS) drive circuit and array multiplexing gates units in accordance with the present disclosure.

FIG. 1D is a block diagram showing a reference local drive unit as including a reference column select (CS) drive circuit and a pair of reference cell local drive gates in accordance with the present disclosure.

FIG. 2A is a circuit diagram illustrating two MRAM cells in column 0 and rows n and n−1 in the N×M MAT shown in FIG. 1B in accordance with the present disclosure.

FIG. 2B is a circuit diagram illustrating two pairs of reference cells in rows n and n−1, respectively, in the N×M MAT shown in FIG. 1B in accordance with the present disclosure.

FIG. 2C is a more detailed representation of the N×M array shown in FIG. 1B, showing connection of source lines (SL) to the access transistors and bit lines (BL) to the MTJs, and a pair of column reference cells placed at the center of the array, and different SL and BL wire RC paths experienced by the bit cells at different rows in accordance with the present disclosure.

FIG. 3A is a block diagram of the R/W circuit shown in FIGS. 1A and 1B in accordance with the present disclosure.

FIG. 3B is a block diagram of global write drivers in the R/W circuit shown in FIG. 3A in accordance with the present disclosure.

FIG. 3C is a block diagram of a reference generator and sense amplifier block in the R/W circuit shown in FIG. 3A in accordance with the present disclosure.

FIG. 3D is a diagram illustrating in further detail the column decoder circuit and the R/W circuit shown in FIGS. 1A and 1B in accordance with the present disclosure.

FIGS. 4A-4C are drawings illustrating a read current path in accordance with the present disclosure, showing a read current from the sense amplifier through the BL read pass gate in the global write driver, through the BLN pass gate in the local drive, through the MTJ and access transistor in a bit cell, and returning through the SLN pass gate of the local drive, through the SL read pass gate in the global write driver, and then to a ground terminal (VSS), in accordance with the present disclosure.

FIGS. 5A-5B are drawings showing a reference current path from a reference generator and sense amplifier block, through a global reference cell write driver, a reference local drive unit, and a reference cell, in accordance with the present disclosure.

FIG. 6 is a circuit diagram of a reference generator for 1T1M MRAM memory cells in accordance with the present disclosure.

FIG. 7 is a circuit diagram of a current sense amplifier for 1T1M MRAM memory cells in accordance with the present disclosure.

FIG. 8 is a circuit diagram of a cross-coupled voltage sense amplifier in accordance with the present disclosure.

FIG. 9 is a circuit diagram illustrating how the current sense amplifier and the cross-coupled voltage sense amplifier are coupled to each other to generate the digital output signal DZ in accordance with the present disclosure.

FIG. 10 is a block diagram showing a reference generator and current sense amplifier block using an alternate design of a current sense amplifier, which includes an analog VBN signal (N bias voltage) for improved performance, in accordance with the present disclosure.

FIG. 11 is a circuit diagram that shows how the alternative design of the current sense amplifier and the cross-coupled voltage sense amplifier are coupled to each other to generate the digital output signal DZ in accordance with the present disclosure.

FIGS. 12A-12D are circuit diagrams of the initial state of the reference cells and normal bit cells in a read operation described with reference to the waveforms shown in FIGS. 13-15 in accordance with the present disclosure.

FIG. 13 is a waveform diagram that describes the operation of the reference generator in the read operation in accordance with the present disclosure.

FIG. 14 is a waveform diagram that describes the operation of the reading a ‘0’ from a memory cell to the sense amplifier output in the read operation in accordance with the present disclosure.

FIG. 15 is a waveform diagram that describes the operation of the reading a ‘1’ from a memory cell to the sense amplifier output in the read operation in accordance with the present disclosure.

### DETAILED DESCRIPTION

Following is brief description of power and signals discussed in some implementation examples described herein:
Power and ground:
   1. VDD—Core device power supply (e.g., 0.9 v).
   2. VSS—ground.
Signals and Nodes:
   1. SAE, SAE1—Sense amplifier enable signal for the current sense amplifier.
   2. SAEB, SAEB1—Inverse of SAE, SAE1.
   3. SAE1D—Delayed SAE1 signal for the current sense amplifier.
   4. SAE2—Sense amplifier enable signal for the cross-coupled voltage sense amplifier.
   5. CM—An analog voltage clamp signal for controlling the gate level of the GBL pass gate to the input the current sense amplifier to prevent a read disturb.
   6. BT, BC, B—Internal current sense amplifier nodes driven by current through MTJ's.
   7. BR—Internal current sense amplifier nodes generated from VREF.
   8. REFT, REFC, REF—Internal reference nodes for sense amplifiers.
   9. VREF—Reference generator output voltage.
   10. VBN—N bias voltage for cascode device for improving performance of the sense amplifier.
   11. 1T1M—A term used to describe a bit cell which has only 1 access transistor and 1 MTJ.
   12. WL—Wordline. WL is connected to the gate of the access transistor of the memory cell. This signal is usually boosted to a high voltage level, for example, 2.0 v.
   13. CS—Column select signal. Enable the decoded column multiplexing gates to allow write and read access to and from memory cells.
   14. DW—Write data. Data to be written to the memory cells.
   15. ENW—Write enable control signal. When enabled, write access to the memory cells is allowed.
   16. ENR—Read enable control signal. When enabled, read access from the memory cells is allowed.
   17. SAE—Sense amplifier enable. Turns on the sense amplifier to sense the analog data from memory cells and outputs to digital data.
   18. SLP—Intermediate node of the P series write driver between VWR and SL.
   19. SLN—Intermediate node of the N series write driver between SL and VSS.
   20. BLP—Intermediate node of the P series write driver between VWR and BL.
   21. BLN—Intermediate node of the N series write driver between BL and VSS.
   22. SL—Source line data. When writing a ‘1’, SL is driven to VWR level. When writing a ‘0’, SL driven to VSS level.
   23. BL—Bit line data. When writing a ‘1’, BL is driven to VSS level. When writing a ‘0’, SL driven to VWR level.
   24. CSP—Column select signal that controls the gate of one of the P series write driver. Switches between VHVWR=0.9 v and VWR=1.8v.
   25. CSB—Column select signal that pre-charges the SL and BL to VSS.

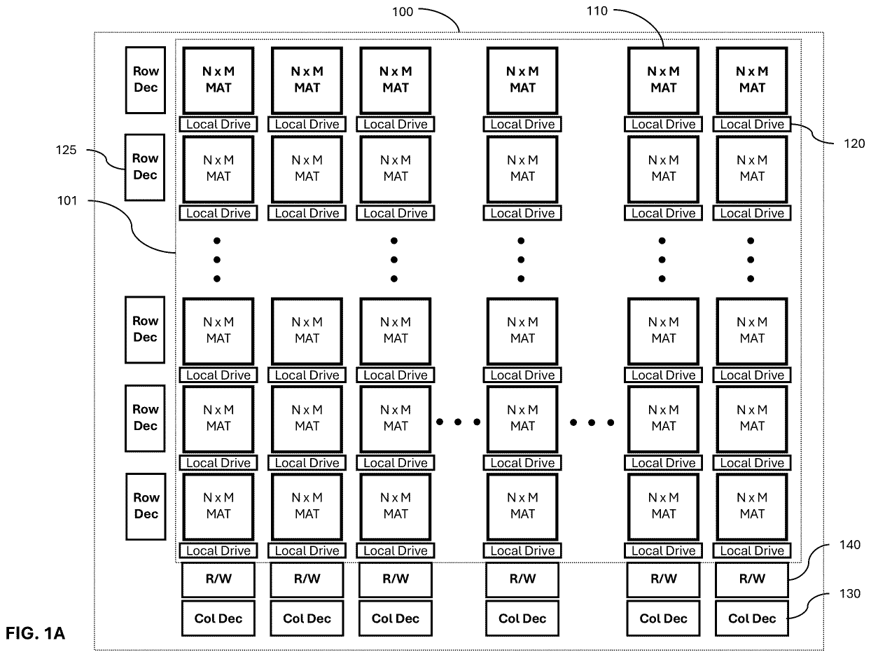

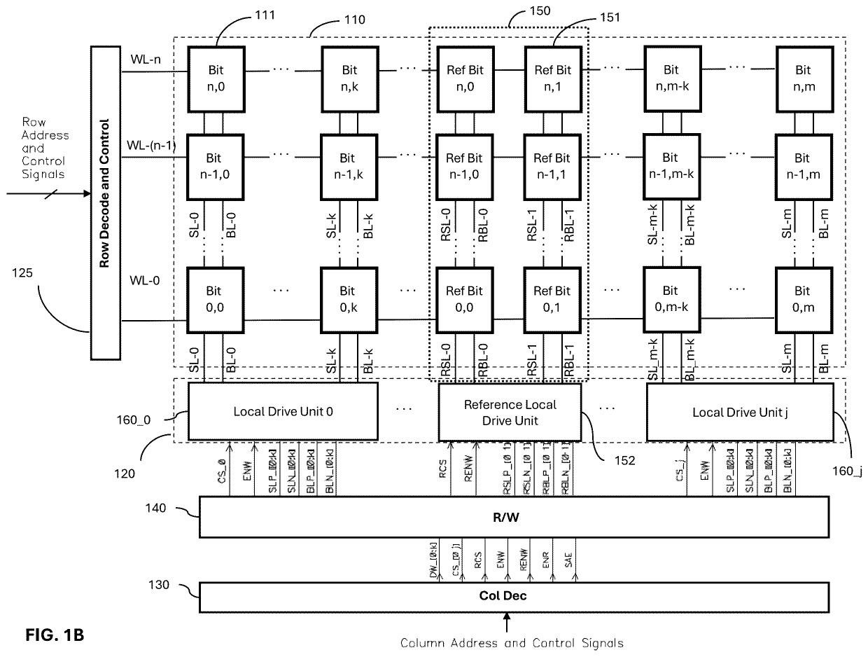

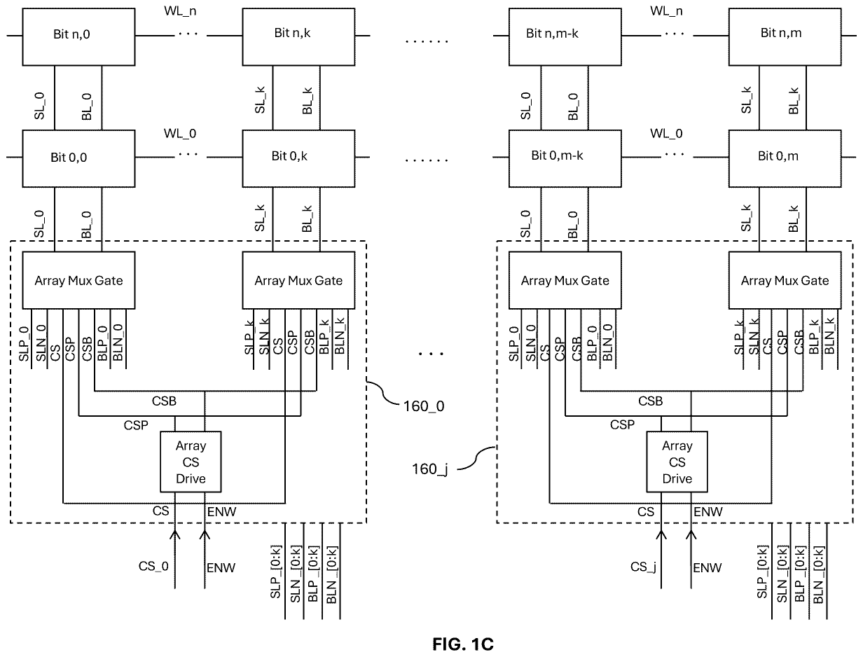

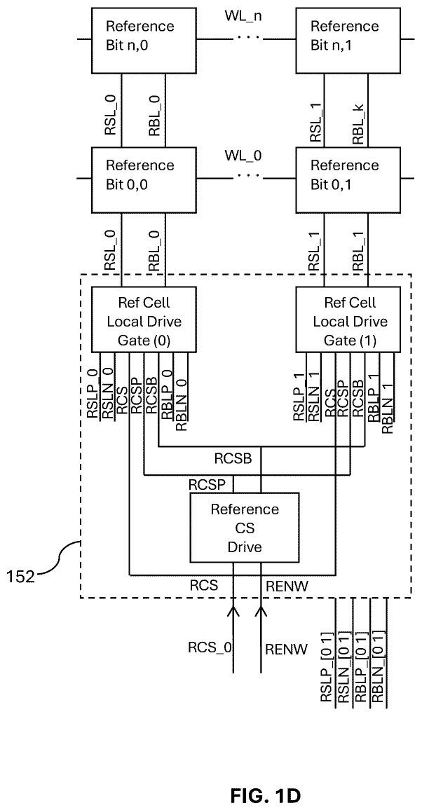

FIG. 1A illustrates an MRAM device 100 in accordance with the present disclosure. As shown, the MRAM device 100 includes an array 101 of MRAM array tiles (MATs) 110 and local drive circuits 120 associated with respective ones of the MATs 110. The MRAM device 100 further includes a row decode and control circuit 125 associated with each row of MATs 110, and a column decode and control circuit 130 and read/write drive circuit 140 associated with each column of the MATs 110.

FIG. 1B illustrates a portion of the MRAM device 100 including an N×M MAT 110 (N=n+1, M=m+1), a Reference Cell Block 150, a local drive circuit 120 including a plurality of local drive units 160, a row decode and control circuit 125, a column decode and control circuit 130, and a read/write drive circuit 140 (R/W), in accordance with the present disclosure. The MAT 110 includes an array of bit cells 111 arranged in N rows and M columns (N=n+1, M=m+1), and at least one reference call block 150. As shown, the reference block 150 is driven by a reference local drive unit 152 and includes reference bit cells (or reference cells) 151 arranged in two columns with m rows, each row with one pair of reference cells 151. As also shown, the columns of the NxM MAT 110 are grouped into j+1 column groups, with k+1 columns in each group. FIG. 1B also shows that the local drive circuit 120 includes j+1 local drive units 160 (e.g., local drive unit 0 to local drive unit j) corresponding, respectively, to the j+1 column groups, and at least one reference local drive unit 152 corresponding, respectively, to the at least one reference bit cell block 150.

FIG. 1C illustrates further details of local drive units 160, showing local drive unit 0 and local drive unit j for driving, respectively, the first k+1 columns and the last k+1 columns of the NxM MRAM Array Tile 110. FIG. 1D illustrates further details of a reference local drive unit 160.

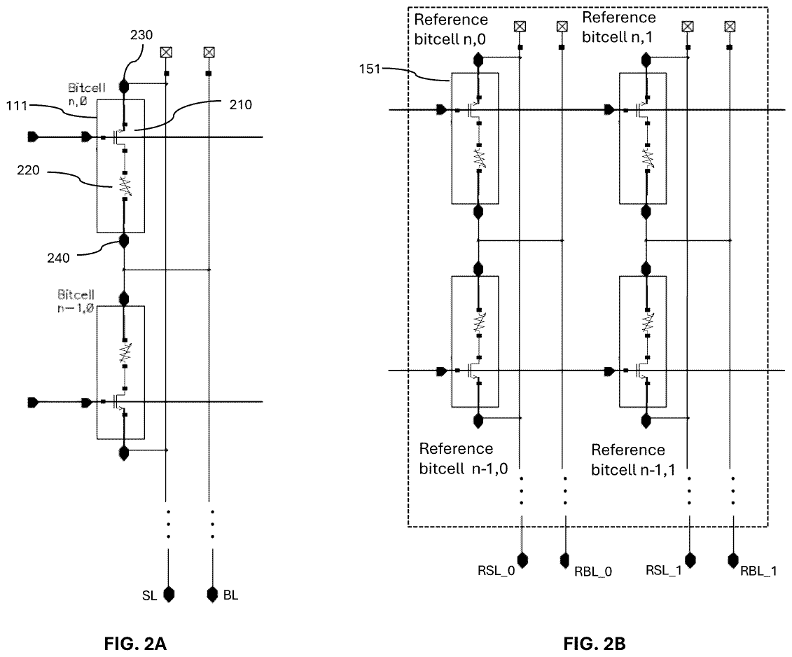

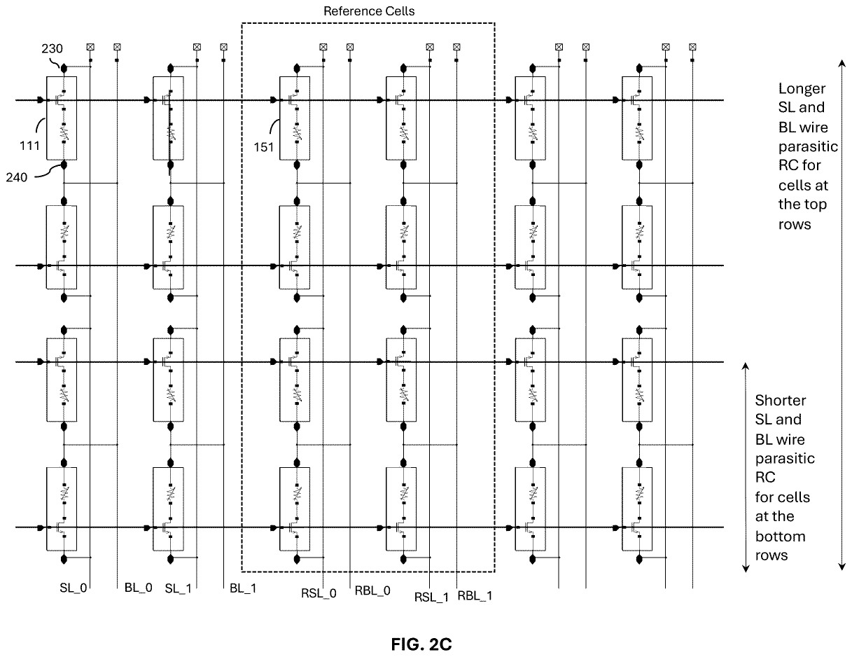

FIG. 2A is a circuit diagram illustrating two MRAM cells 151 (e.g., Bitcell {n,0} and Bitcell {n−1,0}) in column 0, rows n and n−1, respectively, in the N×M MAT 110 shown in FIG. 1B, in accordance with the present disclosure. As shown, each MRAM cell includes an access transistor 210 and an MTJ structure 220 connected in series and has a source line (SL) terminal 230 on the side of the MRAM cell 151 adjacent the access transistor 210 and a bit line (BL) terminal 240 on the side of the MRAM cell 151 adjacent the MTJ 220. The SL terminal 230 is coupled to a source line (SL) of the MAT 110, and the BL terminal 240 is coupled to a bit line (BL) of the MAT 110. FIG. 2B is a circuit diagram illustrating two pairs of reference cells 151 in rows n and n−1, respectively, in the NxM MAT 110 shown in FIG. 1B. As shown in FIG. 2B, each of reference cell {n,0} and reference cell {n−1,0} is coupled between reference source line RSL_0 and reference bit line RBL_0, and each of reference cell {n,1} and reference cell {n−1,1} is coupled between reference source line RSL_1 and reference bit line RBL_1. FIG. 2C is a circuit diagram of a portion of the N×M MAT 110 shown in FIG. 1B in accordance with the present disclosure. As shown in FIG. 2C, a source line (SL) for each column (e.g., SL_0 for column 0) is connected to the SL terminals 230 in the column and a bit line (BL) for each column (e.g., BL_0 for column 0) is connected to the BL terminals 240 in the column. FIG. 2C also shows two columns of reference cells 151 near, e.g., the middle of an array. The diagram also highlights the point that the bit cells at the bottom and top rows experience different SL and BL RC paths.

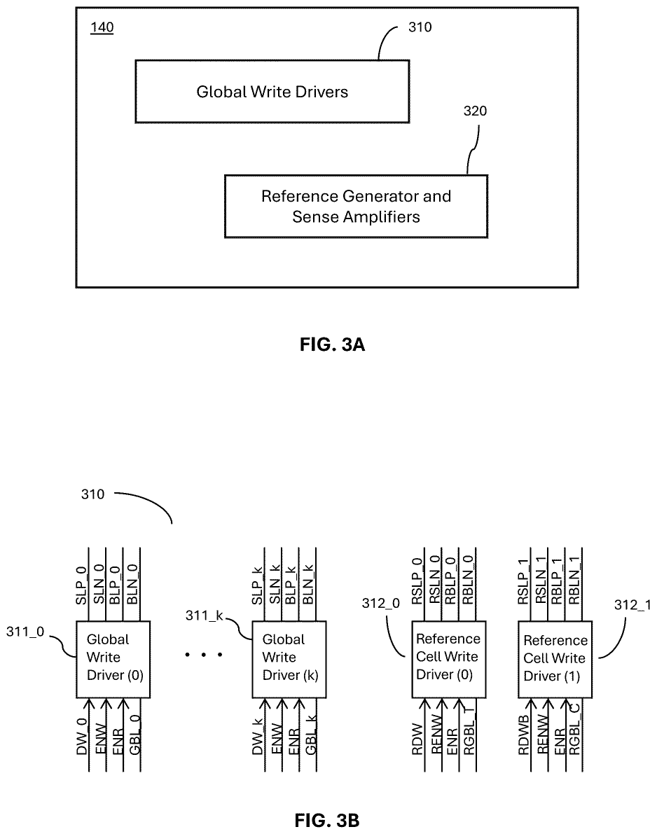

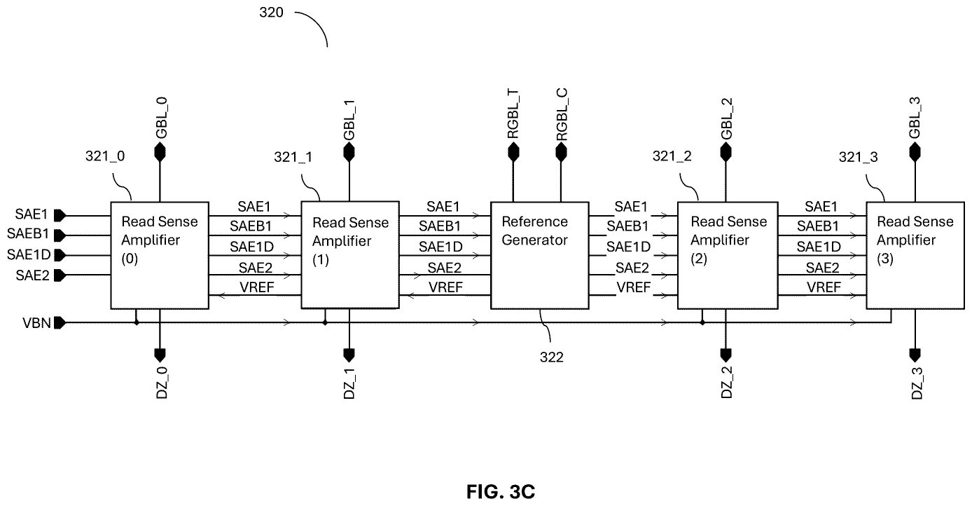

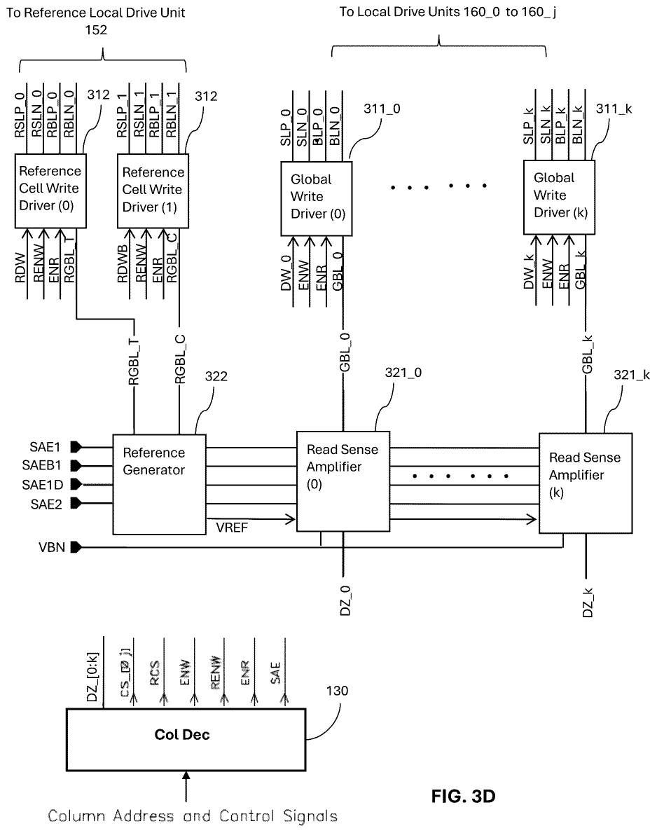

FIG. 3A is a block diagram of the global read/write circuit 300 in accordance with the present disclosure. FIG. 3A shows that the global read/write circuit 300 includes a global write drivers block 310 and a reference generator and sense amplifier block 320. FIG. 3B shows the global write drivers block 310 as including k+1 global write drivers 311 corresponding, respectively, to the k+1 columns of bit cells 111 in each of the j+1 column groups in the NxM MRAM MAT 110, and two reference cell write drivers corresponding, respectively, to two columns of reference cells 151.

FIG. 3C is a block diagram of the reference generator and sense amplifier block 320 showing four current sense amplifiers 321 and a reference generator 322 placed, e.g., in the center of the current sense amplifiers 321, in accordance with the present disclosure. In practice, there can be more or fewer sense amplifiers 321 for each reference generator 322. The reference generator 322 is preferably placed at the center of the sense amplifiers 321 it supports to minimize the distance and possibly variation from the near sense amplifier 321_1 to the far sense amplifier 321_0. The 1T1M read sense amplifier 321 is a type of current sense amplifier. The inputs to the reference generator 322 are sense amplifier control signals, including sense amplifier enable signals SAE1, SAE2, and SAEB1, which is the inverse of SAE1, SAE1D, which is a delayed version of SAE1. The reference generator 322 also receives/outputs currents via the reference global bit lines (RGBL_T, RGBL_C) from the reference bit cells 151, and outputs the reference voltage VREF. The VREF is then applied as a common reference input to the current sense amplifiers 321. Depending on the strength or magnitude of the current coming from the bit cells 111 through the GBL lines, the current sense amplifier 321 senses the difference between this bit cell current magnitude and the reference current magnitude generated from VREF to output a signal DZ with digital level 0 or 1.

As shown in FIG. 3D, the R/W circuit includes k+1 read sense amplifiers 321 and k+1 global write drivers 311 corresponding, respectively, to the k+1 array multiplexing gates in each local drive units. The k+1 sense amplifiers are coupled, respectively, to the k+1 global write drivers 311 via respective global bit lines on one side, and to the k+1 data pads via data paths (not shown) for read data DZ_0 to DZ_k, respectively, on the other side. The k+1 global write drivers are coupled to the k+1 data pads via data paths (not shown) for write data DW_0 to DW_k, respectively. Each of the read sense amplifiers 321 receives the reference voltage VREF, and the control signals SAE1, SAE2, SAEB1 and SAE1D, and may further receive an N bias voltage VBN for cascode device for improving performance of the sense amplifier, as described further below. Each of the k+1 global write drivers receives control signals including a write enable signal ENW (which, when enabled, allow write access to the corresponding bit cells), and a read enable signal ENR (which, when enabled, allow read access from the corresponding bit cells). Each sense amplifier 321 may be a multi-stage sense amplifier with a first stage being a current sense amplifier that converts the small current difference into a differential voltage. A second stage and potentially a third stage are used to amplify the differential voltage of the first stage. Each write driver can be a tri-statable driver connected directly to the global source line (GSL) and global bit line (GBL), as discussed in further detail below.

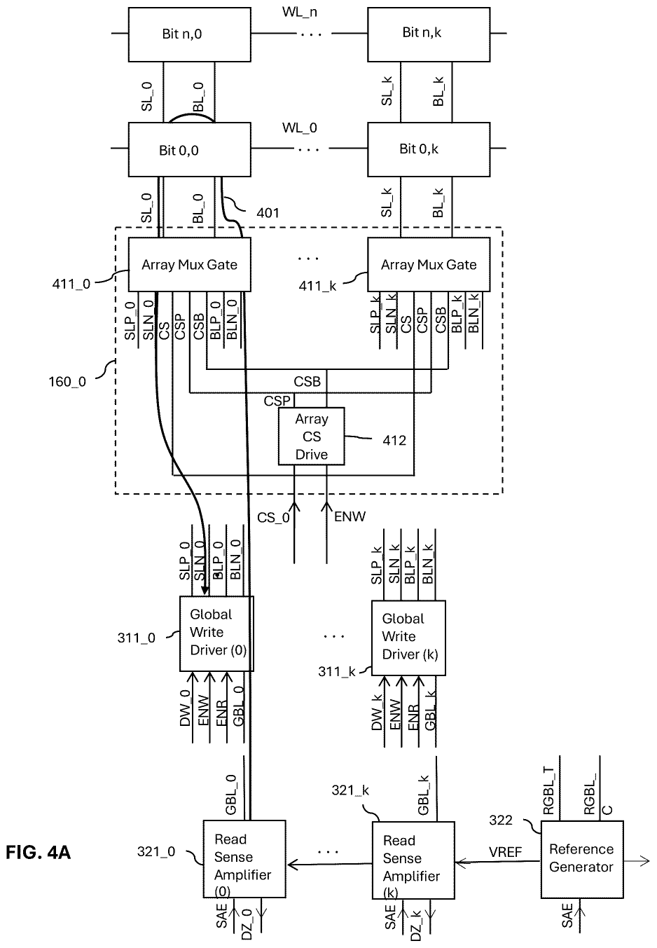

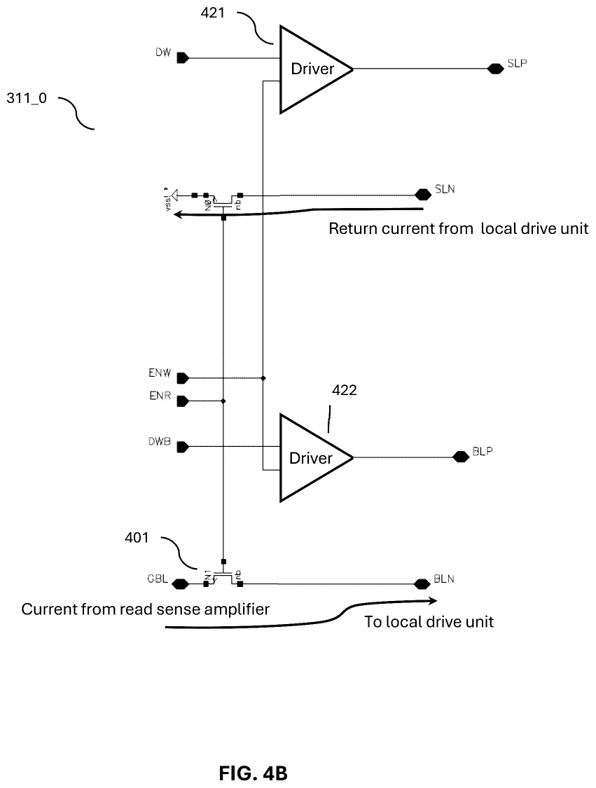

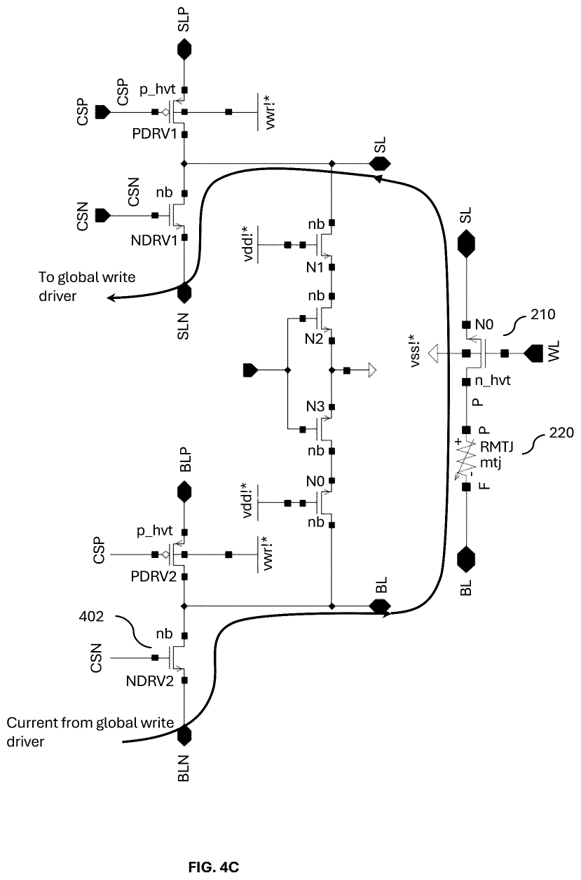

FIGS. 4A to 4C are drawings that show a read current path in which current from a sense amplifier 321_0 travels through a BL read pass gate 401 in a corresponding global write driver 311_0, through the BLN pass gate 402 in the array multiplexing gate 411_0 of a corresponding local drive 160_0, through the MTJ 220 and access transistor 210 in a bit cell 111, and then returns through the SLN pass gate 411 of the local drive 160, through the SL read pass gate 410 in the global write driver 311, and then to VSS 420.

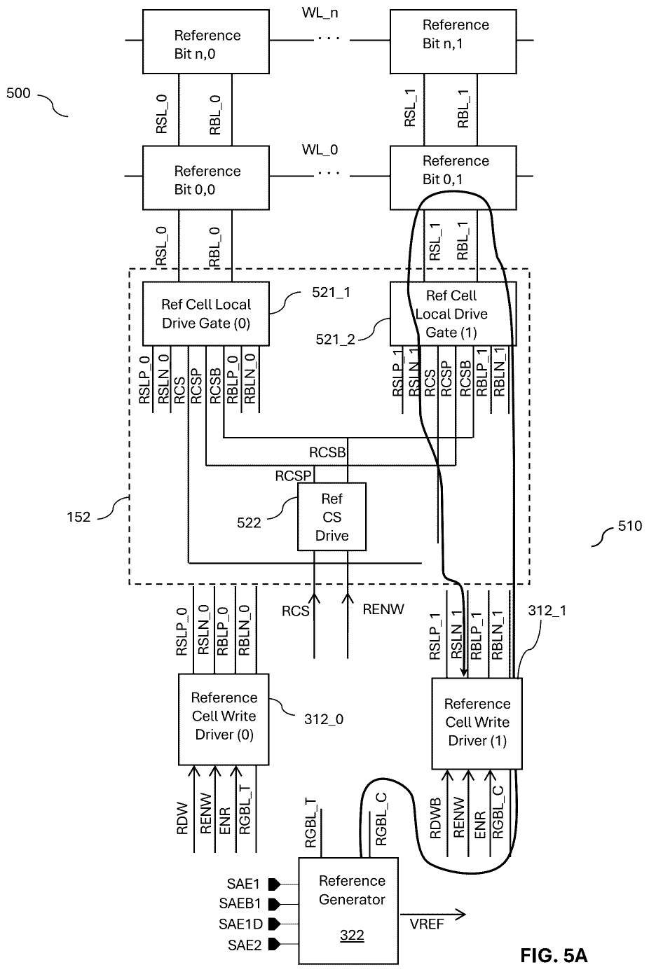

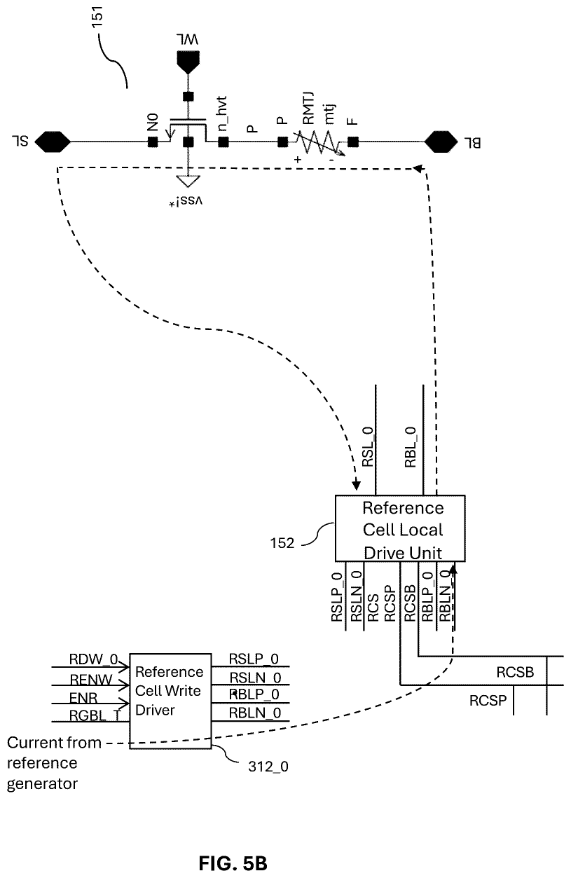

As shown in FIG. 5A, a reference generator circuit (or reference circuit) 500 in accordance with the present disclosure comprises a pair of columns of reference bit cells 151, a reference cell write driver 510 (including a pair of global reference cell write drivers 312_0 and 312_1 and the reference local drive units 152), and a reference generator 320.

In some implementation examples, a reference cell write operation is performed to write data to all the reference cells in advance before the reference generator circuit 500 is used to generate the reference voltage. This reference cell write operation can occur at power up or during test mode operation. The data to a true bit cell and the data to the complement bit cell should be the inverse of each other. For example, for the pair of reference cells on each row (e.g., row 0), if reference bit (0,0) is written with a 0 (Rp), then reference bit (0,1) should be written with a 1 (Rap), and vice versa.

As shown in FIGS. 5A and 5B, a reference current during a read operation is conducted from the reference generator 322 through the memory cells and then returns to the SL input of the reference cell driver 321 which is connected to VSS.

Referring to FIG. 5A, the current path starts with the current from the GBL line of the reference generator 322, which is a type of current sense amplifier. As discussed below, the reference read current during a read operation is used to generate the reference voltage VREF. The read operation for reading from a reference cell is similar to that for reading from a normal cell, so the internal paths inside the reference cell global write driver and the reference local drive unit are similar to those inside the bit cell global write driver and the bit cell local drive units shown in FIGS. 4B-4C.

As shown in FIGS. 4B-4C, to read from a reference cell, ENW stays low (e.g., 0.0 v). This turns off both drivers 421 and 422 for driving write data DW and DWB (the inverse of DW), respectively. Then, ENR is brought high (e.g., 0.9 v), CSP is brought to VWR high (e.g., 1.8 v), and CSN is brought high (e.g., 0.9 v). This turns on N0 and N1 read pass gates, and NDRV1 and NDRV2 gates (of local drive). CSB is brought low (0 v) and thus turns off the pre-charge devices N2 and N3. WL for the corresponding row is brought high (e.g., 2.0 v) and thus turns on the access transistor in the bit cell. Read current from GBL passes N1 read pass gate and reaches the BLN output of the reference cell write driver.

As shown in FIG. 4C, the current from the reference cell write driver enters the local drive via the BLN input and passes NDRV2 (of local drive) to reach the BL terminal of the MTJ. After passing the MTL and the access transistor, the current passes the SL terminal and the NDRV1 (of local drive), and is brought back to the reference cell write driver via the SNL output of the local drive. The current then returns to VSS via the read pass gate N0.

Referring to FIG. 2C and FIGS. 4B-4C, along the read current path, there are parasitic resistances and capacitances on the SL and BL, as well as contact resistances, the resistance of the access transistor and that of the MTJ. Therefore, the read current magnitude or strength is determined by the voltage of the sense amplifier and the sum of all these resistances along the read current path. However, except for the MTJ's, the other resistance components are nearly the same for all columns of cells. As a result, the main factor that differentiates the read current strength of a cell is the cell's MTJ resistance state. If a cell with the MTJ resistance state is 0 (Rp), then the read current magnitude or strength is higher than the cell with MTJ resistance state of 1 (Rap).

As stated previously, for the reference generator to work correctly, a pair of the reference cells should have complementary data to source the current from the RGBL_T and RGBL_C data lines of the reference generator during a read operation. For example, if one cell is ‘0’, the other cell should be ‘1’. If one cell is ‘1’, then the other cell should be ‘0’. The pairing of the reference cells is enabled by the same and specific WL activation on a particular row. This means that, for example, if a reference cell, after a write, has an MTJ resistance state of Rp associated with the RGBL_T line, then the other reference cell of the pair, after a write, should have an MTJ resistance of Rap associated with the RGBL_C line.

The MTJ resistance can vary significantly with respect to process and temperature. The transistors that are built around the MTJ can also vary significantly with process, voltage, and temperature (PVT). As a result, the read current, which is a function of the resistance of the MTJ and these transistors, also vary significantly with PVT.

In certain embodiments, a reference voltage is generated to automatically track these PVT variations regardless of the degree of variations. This reference voltage is applied as an input to the current sense amplifier to be used as a reference to sufficiently and successfully sense or differentiate the current through a bit cell with the MTJ resistance at either a Rp or Rap state.

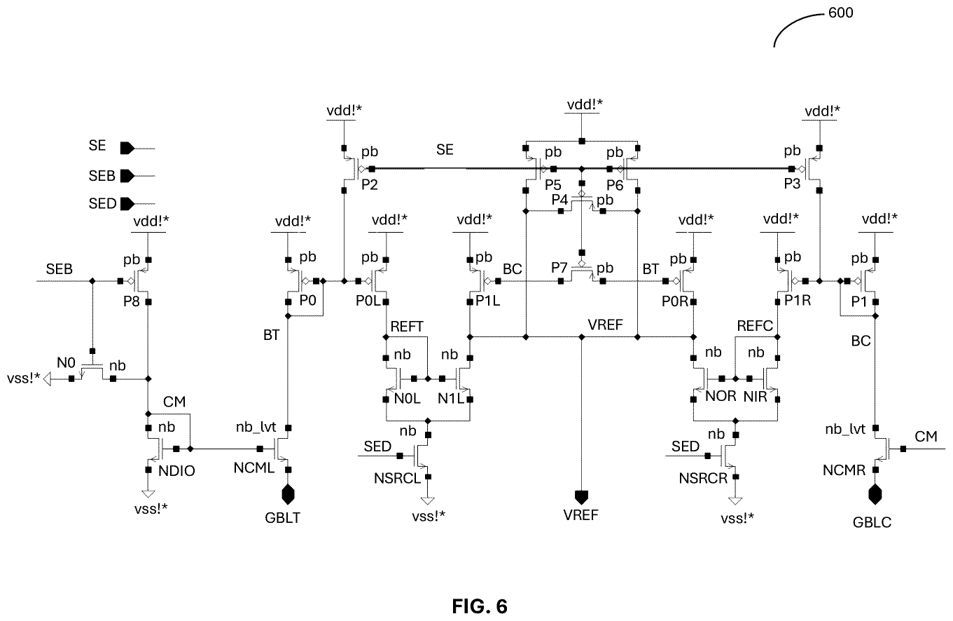

FIG. 6 illustrates a 1T1M reference generator circuit 600, which can be used as the reference generator 322 in accordance with the present disclosure. As shown in FIG. 6, the reference generator circuit 600 has inputs SE, SEB, and SED inputs to receive SE, SEB, and SED signals, respectively, and an output to output a reference voltage VREF, in accordance with the present disclosure. SE represents the sense amplifier enable signal, SEB is the inverse of SE, and SED is a delayed version of SE. The 1T1M reference generator circuit also includes terminals GBLT and GBLC coupled to 2 bidirectional true and complement global bit lines, RGBL_T and RGBL_C, respectively. For example:
The power to the reference generator is VDD (e.g., VDD=0.9 v);
P8 and NDIO together generates the clamp voltage CM;
P2, P3, and P7 are for pre-charging and equalizing the BT and BC nodes to VDD;
P4, P5, and P6 are for pre-charging and equalizing the VREF signal to VDD;
P0L, P1L, N0L, N1L form a P type differential amplifier on the left;
P0R, P1R, N0R, N1R form another P type differential amplifier on the right;
NSRCL and NSCCR are transistors that can enable or disable the amplifiers; and
The output of the left and right amplifiers are tied together to generate VREF.

Operation of the reference voltage generator (or reference generator, or voltage generator) is described below with reference to FIG. 6, where the voltage generator is shown to include a set of interconnected transistors.

Initially, during an idle or pre-charge state, SE=low and that forces SEB=high, which turns on N0, which drives CM to VSS. As a result, both NCML and NCMR are turned off. This cuts off the read current path via CBLT and/or CBLC from the reference generator to the reference cells. Further, SE=low enables P2, P3, P7, which pre-charge node BT and BC to VDD, and SE=low also enables P4, P5, P6, which pre-charge node VREF to VDD.

During a read operation, SE is brought high forcing SEB to be brought low, which turns off N0. P8 and NDIO become a diode connected reference circuit to generate the clamp voltage CM at around 0.55 v. This CM at the gate prevents NCML and NCMR from fully turning on and also prevents the GBLT and GBLC level from going too high where they may unintentionally flip the data in memory cells, a situation known as a read disturb. Additionally, during the read operation, SE being high disables P2, P3, P7, P4, P5, P6. As a result, BT, BC, and VREF are no longer being pre-charged. These nodes are ready to be driven.

Once SE is asserted high and CM is brought high, NCML and NCMR are on. The read current path from the reference generator is enabled, as described above with reference to FIGS. 4B-4E. There are 2 cases with regard to the data on the RGBL_T and RGBL_C lines. As stated previously, the data on RGBL_T and RGBL_C lines should be complementary. So, there are two possible cases:
1. RGBL_T is connected to a memory cell with the MTJ resistance state Rp. RGBL_C is connected to a memory cell with MTJ resistance state Rap.
2. RGBL_T is connected to a memory cell with the MTJ resistance state Rap. RGBL_C is connected to a memory cell with MTJ resistance state Rp.

Here, Rp is the low resistance state, and Rap is high resistance state. As example, Case 1 is used here to describe the remaining operation of the reference generator. In case 1, RGBL_T is connected to a memory cell with MTJ resistance state Rp (equivalent to reading a ‘0’ from the memory cell). RGBL_C is connected to a memory cell with MTJ resistance state Rap (equivalent to reading a ‘1’ from the memory cell). Since RGBL_T path is associated with Rp, the read current on RGBL_T path is higher than the current on RGBL_C. Or, if i(MRp) denotes the current on RGBL_T and i(MRap) denotes the current on RGBL_C, then i(MRp)>i(MRap).

NCML and P0 form a common stage amplifier with PMOS diode connected load for the RGBL_T line. NCMR and P1 form an amplifier of the same stage for RGBL_C line. P0 and P1 are the PMOS diode connected loads. The input to this amplifier stage is the current i(MRp) and i(MRap), respectively, rather voltage. The output of this stage is BT and BC voltage. Therefore, this amplifier stage takes the current as the input and converts it to voltage as the output.

The next stage is a P type differential input amplifier. The inputs are BT and BC. If the output of the left and right amplifiers are tied together, then the output becomes a reference signal VREF that can automatically track the variation of the read current due to process, voltage, and temperature.

Since i(MRp)>i(MRap), this pulls BT slightly lower than BC. This means that v(BT)<v(BC), the voltage level of BT is slightly lower than the voltage level of BC.

Once the BT and BC level is established and stabilized, SED is brought high, which turns on NSRCL and NSRCR to conduct current and enable the differential amplifiers.

Once the differential amplifiers are enabled i(P0L) forces a current through i(N0L), which establishes REFT at a certain voltage level. REFT at the gate of N1L also generates a mirror current of N0L for N1L. Therefore, i(P0L)=i(N0L)=i(N1L). Also, i(P1R) forces a current through i(N1R), which establishes REFC at a certain voltage level. REFC at the gate of N0R also generates a mirror current of N1R for N0R. Therefore, i(P1R)=i(N1R)=i(N0R).

At the input P0L and P1L PMOS devices, v(BT)<v(BC), meaning that VSG of P0L is greater than VSG of P1L. This also means that i(P1L)<i(P0L) which is equivalent to i(P1L)<i(N1L). In this situation, N1L, which now is stronger than P1L, attempts to drive VREF below REFT.

At the inputs of P0R and P1R PMOS devices, v(BT)<v(BC), meaning that VSG of P0R is greater than VSG of P1R. This also means that i(P0R)>i(P1R), which is equivalent to i(P0R)>i(N0R). In this situation, P0R, which now is stronger than N0R, attempts to drive VREF above REFC.

To maintain a constant VREF at equilibrium state, the following condition should be met:

$$i ( P 1 L ) + i ( P 0 R ) = i ( N 1 L ) + i ( N 0 R ) .$$

As a result of the push and pull action of the differential amplifiers and the constant supply of current at equilibrium state, VREF keeps landing midway between REFT and REFC and remains constant throughout the operation until it is pre-charged.

Since REFT and REFC is a direct function of the read current, any variation on the read current will be reflected on REFT and REFC. Therefore, once VREF is generated to land midway between REFT and REFC, then VREF is able to track the variation of the read current due to process, voltage, and temperature.

As shown in FIG. 3C, the output of the reference generator 322, VREF, is connected to a common input to the current sense amplifiers 321 supported by the reference generator 322.

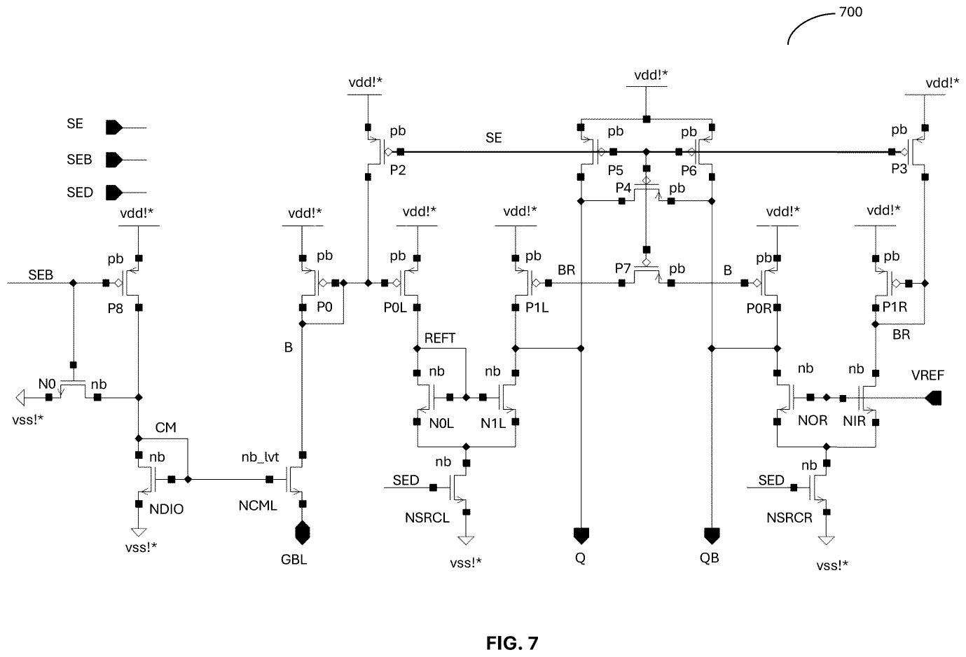

FIG. 7 shows a current sense amplifier circuit 700, which can be used as the sense amplifier 321 discussed above. The current sense amplifier circuit 700 is similar to that of the reference generator circuit 700 except for several differences, including:
The differential amplifier 700 has differential outputs Q and QB;
VREF is connected to the gate of N0R and N1R; and
P1R is configured as a diode-connected load with BR as the load output.

Operation of the current sense amplifier 700 is similar to that of the reference generator 600. Initially during an idle or pre-charge state, SE=low forcing SEB=high, which turns on N0 and drives CM to VSS, which turns off NCML. This cuts off the read current path from the current sense amplifier to the normal memory cells. Further, SE=low enables P2, P3, P7 which pre-charge node BR and B to VDD, and SE=low enables P4, P5, P6 which pre-charge node Q and QB to VDD.

During a read operation, SE is brought high forcing SEB to be brought low, which turns off N0. P8 and NDIO become a diode connected reference circuit to generate the clamp voltage CM at around 0.55 v. SE being brought high also disables P2, P3, P7, P4, P5, and P6. Thus, BT, BC, Q, and QB are no longer being pre-charged. These nodes are ready to be driven.

Once SE is asserted high and CM is brought high, NCML and NCMR are on. The read current path from the current sense amplifier is enabled, as described above with reference to FIGS. 4A-4C.

There are 2 cases with regard to the data on the GBL line: 1) GBL can be connected to a memory cell with the MTJ resistance state Rp, or 2) it can be connected to memory cell with MTJ resistance state Rap.

If GBL is connected to a memory cell with MTJ resistance state Rp, this is equivalent to reading a ‘0’ from the memory cell. If the GBL is connected to a memory cell with MTJ resistance state Rap, this is equivalent to reading a ‘1’ from the memory cell. The current path with Rp cell has higher read current than the path with Rap cell. So i(MRp)>i(MRap).

In some implementation examples, NCML and P0 form a common stage amplifier with PMOS diode connected load for the GBL line. P0 is the PMOS diode connected load. The input to this amplifier stage is the current through the GBL node, i(MRp) or i(MRap), rather the voltage. The output of this stage is the B node. This amplifier stage takes the current as the input and converts it to voltage as the output.

In some implementation examples, the next stage is a P type differential input amplifier on the left side. The inputs are B and BR and the output is Q. For the right side differential amplifier, VREF is connected to N0R and N1R. VREF and the N1R, P1R configuration forces i(N1R)=i(P1R)=i(N0R) and BR to be at a certain voltage level after the amplifier is enabled. The reference current is i(N1R) and BR is an internal output voltage node associated with this reference current. The value of this reference current is always between the read current for cell Rp and cell Rap.

In some implementation examples, if the read current is to the Rp cell, this higher current pulls node B slightly lower than BR associated with the reference current. If the read current is to the Rap cell, this lower current allows P0 to pull node B slightly higher than BR. Once the B node is established and stabilized, SED is brought high turns on NSRCL and NSRCR to conduct current and enable the differential amplifiers. Once the differential amplifiers are enabled, i(P0L) forces a current through i(N0L) which establishes REF at a certain voltage level. REF at the gate of N1L also generates a mirror current of N0L for N1L. Therefore, i(P0L)=i(N0L)=i(N1L).

Thus, when reading a 0 (Rp):
1. At the input of P0L and P1L PMOS devices, v(B)<v(BR) which means that VSG of P0L is greater than VSG of P1L, and that i(P1L)<i(P0L), which is equivalent to i(P1L)<i(N1L). In this situation, N1L, which now is stronger than P1L, attempts to drive Q below REF.
2. At the input of P0R and P1R PMOS devices, v(B)<v(BR), meaning that VSG of P0R is greater than VSG of P1R. This also means that i(P0R)>i(P1R) which is equivalent to i(P0R)>i(N0R). In this situation, P0R, which now is stronger than N0R, attempts to drive QB above VREF.
3. Q driven below REF and QB driven to above VREF creates a differential output voltage (QB-Q).

Reading a ‘1’ operation is very similar to that of reading a ‘0’ operation described above. Reading a ‘1’ causes Q to be driven above REF and QB driven below VREF. This creates a differential output voltage (Q-QB).

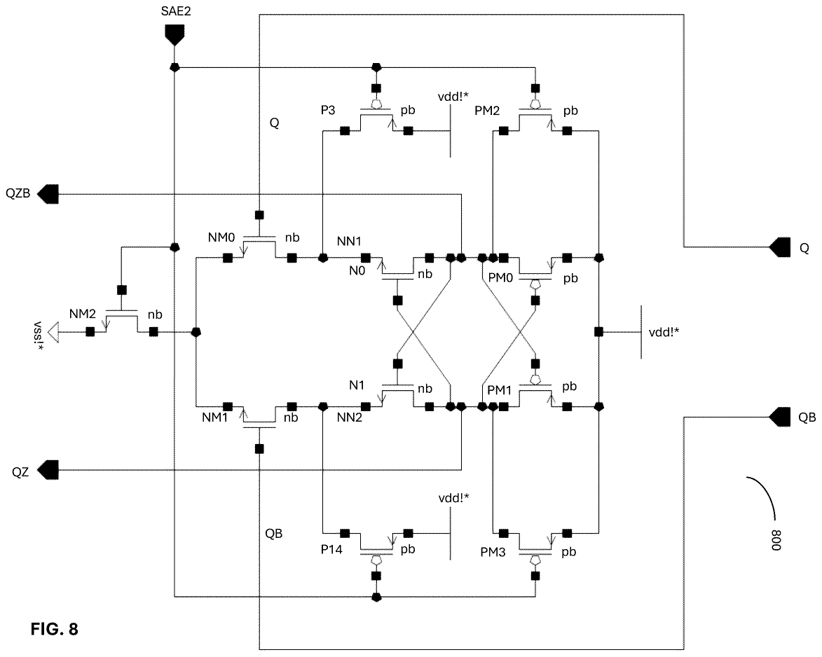

FIG. 8 shows a cross-coupled voltage sense amplifier 800. This amplifier 800 takes the output of the current sense amplifier 700, Q and QB (which are of analog voltage levels) as it's inputs, and generates a full rail to rail level (VSS to VDD) on QZ and QZB.

FIG. 9 shows a circuit diagram of the current sense amplifier 700 shown in FIG. 7, coupled to the voltage sense amplifier 800 shown in FIG. 8, which is coupled to an inverter driver to generate a digital output DZ, in accordance with the present disclosure.

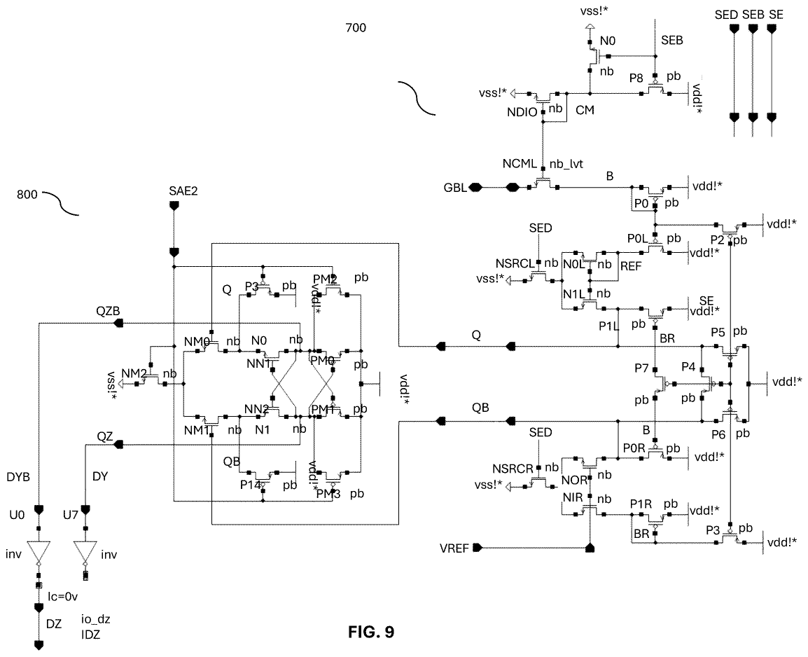

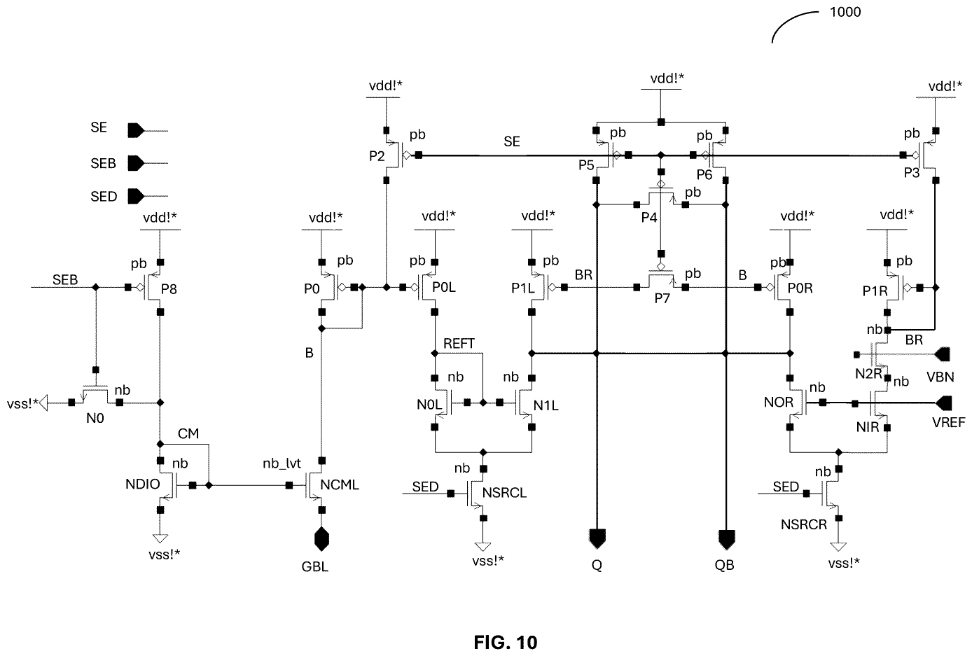

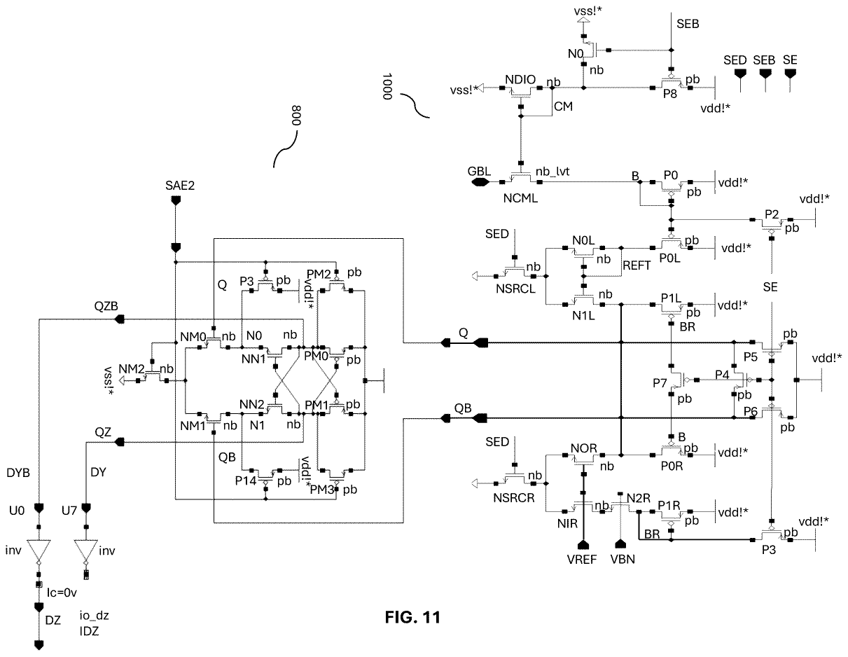

FIGS. 10-11 are circuit diagrams of an alternative design of the current sense amplifier 1000. As shown in FIG. 10, VBN is an analog voltage signal connected to N2R of the alternative current sense amplifier. The cascode device N2R forces a more accurate mirroring of the current between N0R and N1R and, as a result, an improved performance of the differential amplifier at certain extreme PVT corner.

FIG. 11 shows a circuit diagram of the current sense amplifier 1000 shown in FIG. 10, coupled to the voltage sense amplifier 800 shown in FIG. 8, which is coupled to an inverter driver to generate a digital output DZ, in accordance with the present disclosure.

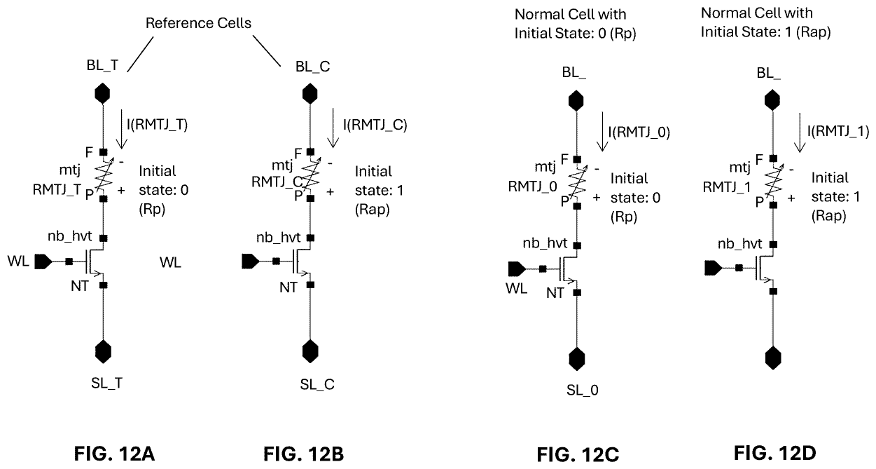

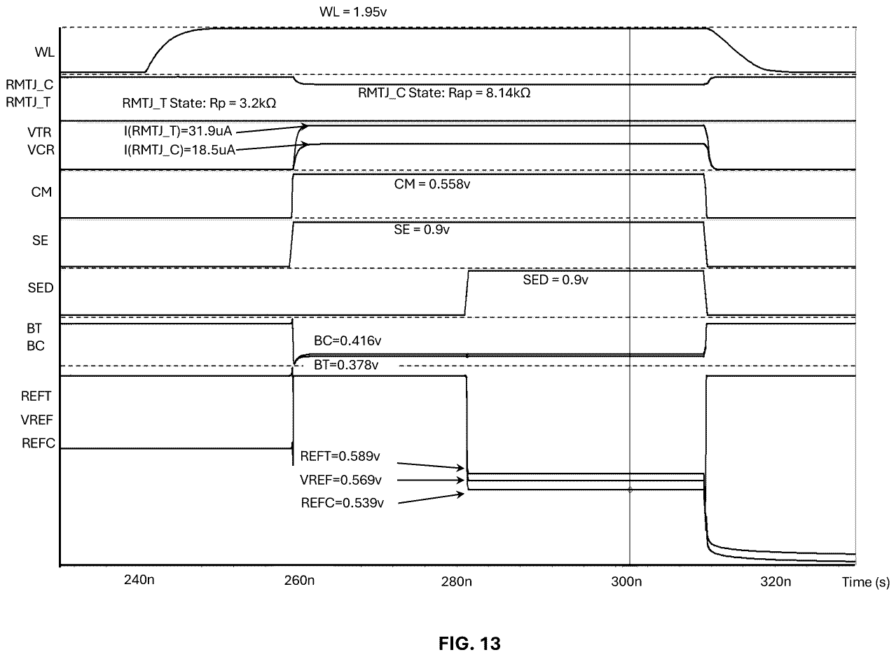

FIGS. 12A-12D are circuit diagrams of reference cells and normal bit cells, showing the initial state of the reference cells and normal cells for read operations to accompany the waveform descriptions shown in FIGS. 13-15. In this example, RGBL_T is connected to the memory cell with MTJ initial state of Rp. RGBL_C is connected to memory cell with MTJ initial state of Rap.

FIG. 13 is a waveform diagram that describes the operation of the reference generator for the case of RGBL_T connected to cells with state Rp and RGBL_C connected to cells with state Rap, as shown in FIGS. 12A and 12B. In this diagram, i(MRp)=i(RMTJ_T) is greater than i(MRap)=i(RMTJ_C). As a result, v(BT) is slightly below v(BC). Once SED is brought high and the differential amplifiers are enabled, VREF always land in the middle between REFT and REFC.

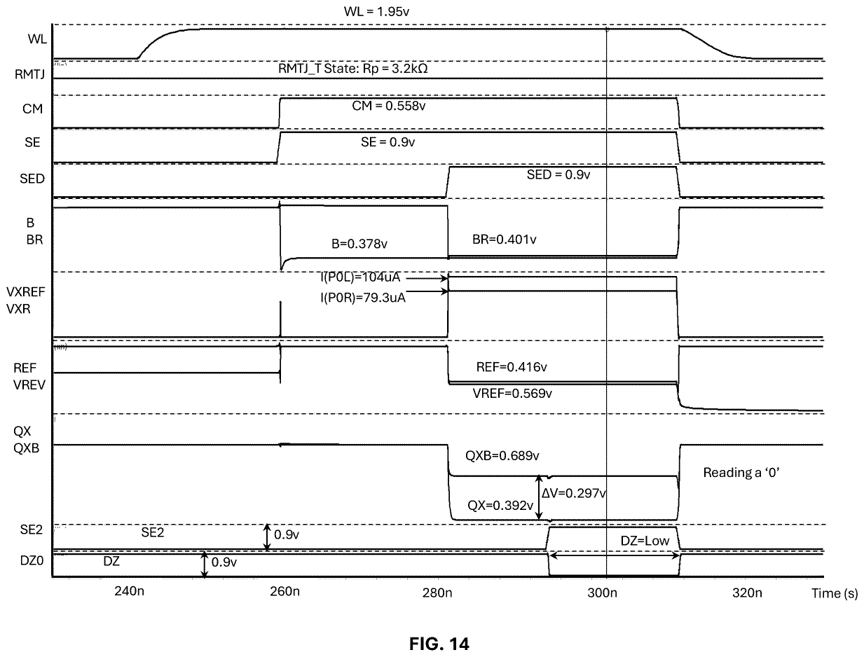

FIG. 14 is a waveform diagram that describes a read operation resulting in a ‘0’ being read from a memory cell based on the sense amplifier output. In this case, v(B)<v(BR) on the left side differential amplifier 700 or 1000 drives the Q node (QX) below REF. v(B)<v(BR) on the right side of the differential amplifier 700 or 1000 drives QB node (QXB) above VREF. This creates a differential output voltage 66 V (QXB-QX) and after passing through the cross-coupled voltage amplifier and the inverter, and a digital DZ low output is generated.

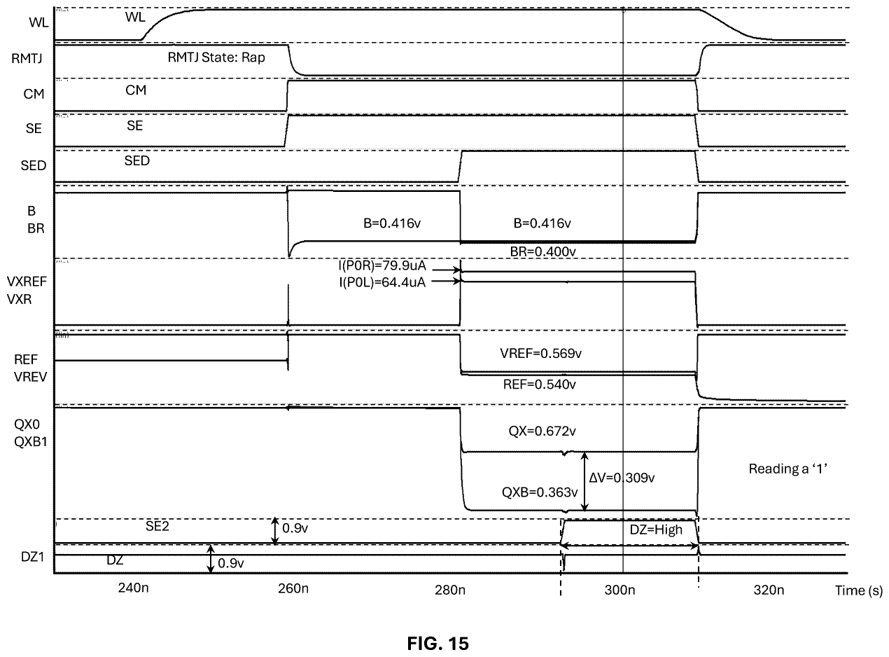

FIG. 15 is a waveform diagram that describes the operation of the reading a ‘1’ from a memory cell to the sense amplifier output. In this case, v(B)>v(BR) on left side differential amplifier drives QX above REF. v(B)<v(BR) on the right side differential amplifier drives QXB below VREF. This creates a differential output voltage ΔV (QX-QXB) and after passing through the cross-coupled voltage amplifier and the inverter, a digital DZ high output is generated.

The reference cell scheme shown in FIG. 2B also accounts for any variation in the cells with respect to the row location. For example, if the WL-n is enabled, then the reference cells in the top row, along with all the other cells on the same WL-n, are also turned on in the top row. The reference cells through which the reference current is conducted would be subjected to the same wire RC delay as any other cells on the same row.

The reference cell scheme in FIG. 2B only show a pair of reference cells ideally placed at the center. In some implementation examples, an MAT may include more than one reference block. For example, if there are significant variation in the cells from left edge to the right edge of the MAT, more reference blocks could be provided and distributed along the row direction, although this would increase the overhead for the layout and chip size.

In summary, the reference generator according to some implementation examples is able to generate a reference voltage that automatically tracks the variation of the resistance (and read current) of the MTJ and transistors due to process, voltage, and temperature variations. It tracks the variation without the need of tuning or adjusting the reference voltage. The current sense amplifier according to some implementation examples takes this reference voltage and uses it as a reference level to compare against the read current and generate a sufficiently and reasonably large differential output (QX, QXB) that can be used to reliably generate a correct digital output for all possible PVT corners.

It will be understood that various aspects or details of the disclosure may be changed without departing from the scope of the disclosure. It is not exhaustive and does not limit the claimed disclosures to the precise form disclosed. Furthermore, the foregoing description is for the purpose of illustration only, and not for the purpose of limitation. Modifications and variations are possible in light of the above description or may be acquired from practicing the disclosure. The claims and their equivalents define the scope of the disclosure. Moreover, although the techniques have been described in language specific to structural features and/or methodological acts, it is to be understood that the appended claims are not necessarily limited to the features or acts described. Rather, the features and acts are described as example implementations of such techniques.

Furthermore, the description of the different examples of implementations has been presented for purposes of illustration and description, and is not intended to be exhaustive or limited to the examples in the form disclosed. Many modifications and variations will be apparent to those of ordinary skill in the art. Further, different examples of implementations may provide different features as compared to other desirable examples. The example, or examples, selected are chosen and described in order to best explain the principles of the examples, the practical application, and to enable others of ordinary skill in the art to understand the disclosure for various examples with various modifications as are suited to the particular use contemplated.

It will also be understood that various aspects or details of the invention may be changed without departing from the scope of the invention. It is not exhaustive and does not limit the claimed inventions to the precise form disclosed. Furthermore, the foregoing description is for the purpose of illustration only, and not for the purpose of limitation. Modifications and variations are possible in light of the above description or may be acquired from practicing the invention. The claims and their equivalents define the scope of the invention.

In some alternative examples of implementations, the function or functions noted in the blocks may occur out of the order noted in the figures. For example, in some cases, two blocks shown in succession may be executed substantially concurrently, or the blocks may sometimes be performed in the reverse order, depending upon the functionality involved. Also, other blocks may be added in addition to the illustrated blocks in a flowchart or block diagram.

It will also be understood that, although the terms first, second, etc., are, in some instances, used herein to describe various elements, these elements should not be limited by these terms. These terms are only used to distinguish one element from another. For example, a first circuit could be termed a second circuit, and, similarly, a second circuit could be termed a first circuit, without departing from the scope of the various described implementation examples. The first widget and the second widget are both widget, but they are not the same condition unless explicitly stated as such.

The terminology used in the description of the various described implementation examples herein is for the purpose of describing particular implementation examples only and is not intended to be limiting. As used in the description of the various described implementation examples and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

The foregoing description, for purpose of explanation, has been described with reference to specific implementation examples. However, the illustrative discussions above are not intended to be exhaustive or to limit the scope of the claims to the precise forms disclosed. Many modifications and variations are possible in view of the above teachings. The implementation examples were chosen in order to best explain the principles underlying the claims and their practical applications, to thereby enable others skilled in the art to best use the implementation examples with various modifications as are suited to the particular uses contemplated.

What is claimed is:

1. A resistive-type memory device, comprising:
at least one memory array, the at least one memory array including a first memory array, the first memory array including a plurality of rows and a plurality of columns, the plurality of columns including at least one column group, the at least one column group including a first column group, the first column group including a number of columns of bit cells and a pair of columns of reference cells, the pair of columns of reference cells including a pair of reference cells configured to store complementary data values in each row of the plurality of rows; and
at least one reference generator and sense amplifier block corresponding, respectively, to the at least one column group, the at least one reference generator and sense amplifier block including a first reference generator and sense amplifier block corresponding to the first column group, the first reference generator and sense amplifier block including a reference generator corresponding to the pair of columns of reference cells and a number of sense amplifiers, the number of sense amplifiers including a respective sense amplifier corresponding, to each column of the number of columns of bit cells;
wherein the reference generator is configured to output a reference voltage to each of the number of sense amplifiers during a read operation to read from one or more bit cells in a row of the memory array, the reference voltage being midway between a first voltage and a second voltage, the first voltage being a function of a first current through a first reference cell, the second voltage being a function of a second current through a second reference cell, the first reference cell and the second reference cell being a pair of reference cells in the row and in the pair of columns of reference cells.

2. The resistive-type memory device of claim 1, wherein the reference generator includes first and second amplifier stages, the first amplifier stage is configured to generate a third voltage and a fourth voltage in response to the first current and the second current during the read operation, the second amplifier stage is configured to generate the reference voltage in response to the first voltage and the second voltage.

3. The resistive-type memory device of claim 2, wherein the second amplifier stage includes first and second differential amplifiers; and wherein:
the first differential amplifier has a pair of inputs configured to receive the third voltage and the fourth voltage, respectively, and a first internal reference node configured to reach the first voltage in response to the third voltage and the fourth voltage;
the second differential amplifier has a pair of inputs configured to receive the fourth voltage and the third voltage, respectively, and a second internal reference node configured to reach the second voltage in response to the fourth voltage and the third voltage; and
the first differential amplifier and the second differential amplifier each has an output coupled to the output of the reference generator.

4. The resistive-type memory device of claim 2, wherein the reference generator further includes a first input configured to conduct the first current, and a second input configured to conduct the second current, wherein the first amplifier stage includes a first transistor having a current-carrying terminal coupled to the first input, and a second transistor having a current-carrying terminal coupled to the second input, and wherein the reference generator further includes a clamping circuit configured to generate a clamp voltage during the read operation, the clamp voltage being applied to a gate terminal of the first transistor and a gate terminal of the second transistor thereby preventing the first current and the second current from being above a predetermined threshold current.

5. The resistive-type memory device of claim 1, wherein a respective sense amplifier of the number of sense amplifiers includes a current sense amplifier configured to receive the reference voltage from the reference generator and a read current from a respective bit cell in the row of memory array during the read operation, and to output a differential voltage indicating a level of the read current.

6. The resistive-type memory device of claim 5, wherein the current sense amplifier includes third and fourth differential amplifiers configured to output the differential voltage in response to the read current and the reference voltage.

7. The resistive-type memory device of claim 1, further comprising:
a plurality of local drive units, each respective local drive unit being coupled to a respective column of the plurality of columns via a respective source line (SL) and a respective bit line (BL), the plurality of local drive units including first and second local drive units corresponding to the pair of columns of reference cells, respectively.

8. The resistive-type memory device of claim 7, further comprising
a plurality of global driver circuits including a number of global driver circuits corresponding, respectively, to the number of sense amplifiers, and first and second global driver circuits corresponding to first and second inputs of the reference generator, respectively.

9. The resistive-type memory device of claim 8, wherein, during the read operation, the first global driver circuit is configured to drive the first current between the first input of the reference generator and the first local drive unit, and the first local drive unit is configured to drive the first current between the first global driver circuit and the first reference cell, and wherein during the read operation, the second global driver circuit is configured to drive the second current between the second input of the reference generator and the second local drive unit, and the second local drive unit is configured to drive the second current between the second global drive circuit and the second reference cell.

10. The resistive-type memory device of claim 9, wherein, during the read operation, a respective global driver circuit of the number of global driver circuits is configured to drive a read current between a respective sense amplifier of the number of sense amplifiers and a respective local drive unit, and the respective local drive unit is configured to drive the read current between the respective global driver circuit and a respective bit cell in the row of the memory array.

11. A method of operating a resistive-type memory device, the resistive-type memory device including at least one memory array, the at least one memory array including a first memory array, the first memory array including a plurality of rows and a plurality of columns, the plurality of columns including at least one column group, the at least one column group including a first column group, the first column group including a number of columns of bit cells, the method comprising:
writing reference cell data into a pair of columns of reference cells associated with the first column group, whereby a pair of reference cells in each row of the pair of columns of reference cells store complementary data values; and
performing a read operation to read one or more bit cells in a selected row of the memory array, including:
driving a first current through a first reference cell and a second current through a second reference cell, the first reference cell and the second reference cell being a pair of reference cells in the selected row and in the pair of columns of reference cells;
outputting a reference voltage, the reference voltage being midway between a first voltage and a second voltage, the first voltage being a function of the first current, the second voltage being a function of the second current; and
applying the reference voltage to one or more current sense amplifiers configured to sense one or more read currents from the one or more bit cells, respectively.

12. The method of claim 11, wherein the reference generator includes first and second amplifier stages, the first amplifier stage is configured to generate a third voltage and a fourth voltage in response to the first current and the second current during the read operation, the second amplifier stage is configured to generate the reference voltage in response to the first voltage and the second voltage.

13. The method of claim 12, wherein the second amplifier stage includes first and second differential amplifiers; and wherein:
the first differential amplifier has a pair of inputs configured to receive the third voltage and the fourth voltage, respectively, and a first internal reference node configured to reach the first voltage in response to the third voltage and the fourth voltage;
the second differential amplifier has a pair of inputs configured to receive the fourth voltage and the third voltage, respectively, and a second internal reference node configured to reach the second voltage in response to the fourth voltage and the third voltage; and
the first differential amplifier and the second differential amplifier each has an output coupled to the output of the reference generator.

14. The method of claim 12, wherein the reference generator further includes a first input configured to conduct the first current, and a second input configured to conduct the second current, wherein the first amplifier stage includes a first transistor having a current-carrying terminal coupled to the first input, and a second transistor having a current-carrying terminal coupled to the second input, and wherein the reference generator further includes a clamping circuit configured to generate a clamp voltage during the read operation, the clamp voltage being applied to a gate terminal of the first transistor and a gate terminal of the second transistor thereby preventing the first current and the second current from being above a predetermined threshold current.

15. The method of claim 11, wherein a respective sense amplifier of the one or more sense amplifiers includes a current sense amplifier configured to receive the reference voltage from the reference generator and a read current from a respective bit cell in the row of memory array during the read operation, and to output a differential voltage indicating a level of the read current.

16. The method of claim 15, wherein the current sense amplifier includes third and fourth differential amplifiers configured to output the differential voltage in response to the read current and the reference voltage.

17. The method of claim 11, wherein driving a first current from a reference generator through a first reference cell and a second current from the reference generator through a second reference cell includes:
driving the first current using a first local drive unit and driving the second current using a second local drive unit, the first and second local drive units corresponding to the pair of columns of reference cells, respectively.

18. The method of 17, wherein driving a first current from a reference generator through a first reference cell and a second current from the reference generator through a second reference cell further includes:
driving the first current using a first global driver circuit and driving the second current using a second global driver circuit, the first and second global driver circuits corresponding to first and second inputs, respectively, of a reference generator that outputs the reference voltage.

19. The method of claim 18, wherein, during the read operation, the first global driver circuit is configured to drive the first current between the first input of the reference generator and the first local drive unit, and the first local drive unit is configured to drive the first current between the first global driver circuit and the first reference cell, and wherein during the read operation, the second global driver circuit is configured to drive the second current between the second input of the reference generator and the second local drive unit, and the second local drive unit is configured to drive the second current between the second global drive circuit and the second reference cell.

20. The method of claim 11, further comprising, during the read operation, driving each of one or more read currents between a respective sense amplifier of the one or more sense amplifiers and a respective bit cell of the one or more bit cells.
